(19) United States
(12) Patent Application Publication
(10) Pub. No.: US 2025/0031310 A1
(43) Pub. Date: Jan. 23, 2025

(54) POWER SEMICONDUCTOR MODULE

(71) Applicant: Robert Bosch GmbH, Stuttgart (DE)

(72) Inventors: Jan Homoth, Reutlingen (DE); Daniel Schweiker, Ludwigsburg (DE); Dominik Alexander Ruoff, St. Johann (DE); Matthias Boesing, Ludwigsburg (DE); Philipp Mueller, Stuttgart (DE)

(21) Appl. No.: 18/763,021

(22) Filed: Jul. 3, 2024

(30) Foreign Application Priority Data
Jul. 20, 2023 (DE) 10 2023 206 890.7

(51) Int. Cl. H05K 1/18

(52) U.S. Cl. CPC H05K 1/181; H05K 2201/10166; H05K 2201/10181

(57) ABSTRACT

A power semiconductor module. The power semiconductor module includes a circuit carrier and at least one semiconductor switch, in particular a semiconductor switch half-bridge, connected to the circuit carrier. The circuit carrier includes an electrically insulating layer, in particular a ceramic layer, and two electrically conductive layers which are separated from one another by an insulating region, in particular an insulating trench, and are both connected to the electrically insulating layer. The electrically conductive layers are both electrically connected to a switching path connection of the semiconductor switch. The power semiconductor module includes at least one metal shaped body, which is connected to the electrically conductive layer and configured to melt when the predetermined temperature is exceeded, to overcome the insulating region, and to connect the electrically conductive layers separated from one another by the insulating region electrically, in particular low-ohmically.

### CROSS REFERENCE

The present application claims the benefit under 35 U.S.C. § 119 of German Patent Application No. DE 10 2023 206 890.7 filed on Jul. 20, 2023, which is expressly incorporated herein by reference in its entirety.

### FIELD

The present invention relates to a power semiconductor module. The power semiconductor module includes a circuit carrier and at least one semiconductor switch, in particular a semiconductor switch half-bridge, connected to the circuit carrier.

### BACKGROUND INFORMATION

A short-circuit-resistant IGBT module, in which an additional layer facilitates a stable short circuit, is described in German Patent Application No. DE 198 43 309 A1. The layer is brought into contact with the main electrodes of the semiconductor chip as a foil, as a paste or as a component of the solder. The layer contains silver, for example, and, together with the semiconductor material, forms a eutectic, the melting point of which is lower than the melting point of the two partner materials.

### SUMMARY

According to the present invention, the circuit carrier of the power semiconductor module of the aforementioned type comprises an electrically insulating layer, in particular a ceramic layer, and two electrically conductive layers which are separated from one another by an insulating region, in particular an insulating trench, and are both connected to the electrically insulating layer. The electrically conductive layers are both electrically connected to a switching path connection of the semiconductor switch. According to an example embodiment of the present invention, the power semiconductor module comprises at least one or only one metal shaped body, which is connected to the electrically conductive layer and configured to melt when the predetermined temperature is exceeded, to overcome the insulating region, and to connect the electrically conductive layers separated from one another by the insulating region electrically, in particular low-ohmically.

The semiconductor switch can thus advantageously be safely short-circuited.

In particular in electric vehicles comprising an electronic control unit and an inverter for supplying current to an electric drive machine of the vehicle, it has been discovered that a large mechanical counter torque can be generated by the currents induced in the machine that causes very hard braking of the vehicle if the control unit or the inverter fail.

The power semiconductor module configured in this way according to the present invention, which is part of an inverter of the electric vehicle, for example, advantageously makes it possible to produce a safe short circuit of the stator coils of the electric machine, so that such a hard braking behavior of the electric vehicle in the event of a failure of the driving electronics can be prevented.

The insulating region, in particular the insulating trench, is preferably formed by a surface area of the circuit carrier, in particular a component side of the circuit carrier, on which the electrically conductive layers are mounted as a rewiring structure. An outward-facing surface of the insulating region is preferably formed by the electrically insulating layer of the circuit carrier.

According to an example embodiment of the present invention, the circuit carrier is preferably formed by a ceramic circuit carrier comprising an electrically insulating ceramic layer and at least two electrically conductive layers. The circuit carrier is a DCB (direct copper bonded) substrate, an AMB (active metal brazed) substrate, an IMS (insulated metal substrate), for instance, or an HTCC (high temperature cofired ceramics) circuit carrier or a LTC (low temperature cofired ceramics) circuit carrier, a printed circuit board, or a leadframe, also referred to as a stamped grid.

The semiconductor switch is preferably a MOSFET, a MISFET, an IGBT (insulated-gate bipolar transistor), a transistor, a SiC FET, GaN FET or GaO FET, or a diamond semiconductor switch. The semiconductor switch can be an IGBT (insulated-gate bipolar transistor) or a FET (field emission transistor).

The metal shaped body can preferably be used to short-circuit a bypass diode, which is inherently embodied in the semiconductor switch and produces much heat when current flows through it. The bypass diode thus constitutes a heat source that can heat the semiconductor to the point that the metal shaped body melts and the short circuit is effectively formed.

The electrically conductive layer of the circuit carrier is preferably a copper layer. The electrically insulating layer of the circuit carrier is preferably a ceramic layer, aluminum oxide layer or aluminum nitride layer, or a silicon nitride layer.

In another example embodiment of the present invention, the electrically insulating layer, in particular the ceramic layer, is formed by a boride or a carbide. The electrically insulating layer is a silicon carbide layer, a boron carbide layer, or a boron nitride layer, for example.

In a preferred embodiment of the present invention, the power semiconductor module, in particular the semiconductor switch half-bridge, comprises a high-side semiconductor switch and a low-side semiconductor switch. The power semiconductor module is further preferably configured such that, for each semiconductor switch, in particular the high-side semiconductor switch and the low-side semiconductor switch, at least one metal shaped body is disposed such that each of the semiconductor switches can be short-circuited when the predetermined temperature, in particular a eutectic temperature point, is exceeded.

In a preferred embodiment of the present invention, the metal shaped body is formed by a eutectic. It is thus advantageously possible that all components, in particular alloy components, change from the solid aggregate state to the liquid aggregate state at the predetermined temperature. This advantageously results in a sudden volume expansion, so that the bridging of a short-circuit path within the power semiconductor module can be accelerated by the volume expansion.

In a preferred embodiment of the present invention, the electrically conductive layers are disposed in a common plane formed by the electrically insulating layer. The electrically conductive layers are preferably each formed by a conductor track of the circuit carrier. The short circuit of the semiconductor switches can thus advantageously be formed on the circuit carrier in a cost-efficient manner.

In a preferred embodiment of the present invention, the metal shaped body is formed by a metal shaped part, in particular a solder preform, which is connected to the circuit carrier in a material-locking manner with a solder. The solder preferably has a lower melting temperature than the metal shaped part. The metal shaped body can thus advantageously be connected to the circuit carrier, in particular assembled, together with other electronic components, in particular the semiconductor switches, during an assembly process, in particular an automated assembly process.

In another embodiment of the present invention, the metal shaped part is glued to the circuit carrier using an adhesive. This advantageously makes it possible to fix the position during extrusion-coating.

The adhesive is an epoxy adhesive or silicone adhesive, for example.

In a preferred embodiment of the power semiconductor module of the present invention, the semiconductor switches and the metal shaped body, further preferably at least a part of the circuit carrier, are embedded by means of a plastic compound, in particular a molding compound. The metal shaped body is designed to create a gap between the plastic compound and the circuit carrier in the area of the insulating region when it melts and increases in volume, and thus bridge the insulating region as it expands and spreads into the gap and electrically connect the electrically conductive layers to one another.

This advantageously makes it possible to create a type of short circuit safety fuse in the power semiconductor module, which is embedded in the power semiconductor module together with the electronic components, in particular the power semiconductor switches, or other additional electronic components. The short circuit protection can thus cost-efficiently be a fixed electronic component of the power semiconductor module.

In a preferred example embodiment of the present invention, in the area of the insulating region, the circuit carrier comprises an adhesion-reducing layer which covers the insulating layer or also the electrically conductive layer. The molding compound can advantageously be detached there from the circuit carrier, in particular easily, when the metal shaped body expands.

The ratio of the circuit carrier thickness to the thickness of the molding compound is preferably 1 to 5.

In a preferred example embodiment of the present invention, the adhesion-reducing layer is a lacquer layer. The lacquer layer is a solder resist layer, for example. In another embodiment, the layer is a plastic layer, for example a gel layer or silicone gel layer. In another embodiment, the layer is a particle layer. This advantageously makes it possible to reduce adhesion in the area of the insulating region for the casting compound.

In a preferred example embodiment of the present invention, the electrically conductive layers, in particular the conductor tracks, in the area of the insulating region are coated with a solder, in particular a tin layer. This advantageously makes it possible to accelerate the material-locking, in particular electrically conductive, connection of the electrically conductive layers when the liquefied metal shaped body flows in the gap.

In a preferred example embodiment of the present invention, the metal shaped body is formed by a metal foam. The metal foam, which comprises a metal grid and volumes of air enclosed by the metal grid, can advantageously melt easily when heated, because the heat capacity of the thus formed metal shaped body is smaller for the same volume than it is for a solid metal shaped body.

In a preferred example embodiment of the present invention, the metal shaped body comprises tin. Other advantageous components of the metal shaped body are indium, bismuth, lead, copper, silver, antimony, gold, aluminum, germanium, silicon or a combination of the aforementioned metals.

It is thus advantageously possible to reliably electrically connect the electrically conductive layers at a predetermined temperature, in particular at a eutectic temperature point.

The predetermined temperature is preferably between 400 and 700 degrees Celsius, further preferably between 450 and 550 degrees Celsius, and particularly preferably in the range of 500 degrees Celsius. This advantageously makes it possible to reliably distinguish between short-term heating during operation of the power semiconductor module and a fault of the power semiconductor module.

In a preferred example embodiment of the power semiconductor module of the present invention, at least one metal shaped body is formed on each of the two electrically conductive layers. The metal shaped bodies can preferably flow toward one another when they melt. This advantageously makes it possible to accelerate the short-circuit process of the semiconductor switches when the predetermined temperature is exceeded. The aforementioned gap, which can be formed in the area of the insulating region when the metal shaped bodies liquefy and consequently expand, can thus be closed quickly from two sides by means of the liquid metal of the metal shaped body that spreads into the gap.

The present invention also relates to an electric vehicle comprising at least one power semiconductor module of the type described above. The electric vehicle comprises an inverter with at least one power semiconductor module, wherein the inverter is connected to at least one electric drive machine of the electric vehicle. The inverter is configured to supply current to the drive machine to produce a rotating magnetic field. In an electric vehicle comprising the power semiconductor module, this advantageously makes it possible to prevent hard braking in the event of a fault in the power electronics, so that a vehicle comprising a thus configured inverter can gradually coast to a stop with the thus short-circuited semiconductor switch half-bridge within the power semiconductor module. A high-voltage battery connection, in particular a positive connection or a negative connection, can be low-ohmically connected to the phase connection by means of the metal bridge.

The present invention also relates to a method for deactivating an electric vehicle, in particular an inverter of the electric vehicle. In the method, at least one power semiconductor switch of the inverter is short-circuited by means of a metal shaped part that melts when the inverter overheats. The metal shaped part is further preferably disposed and configured to bridge two spaced apart electrically conductive layers of a circuit carrier of the inverter. The short circuit protection of the electric vehicle can thus advantageously be configured on the circuit carrier—in particular as an electronic component of the circuit carrier.

In a preferred embodiment of the method of the present invention, the power semiconductor is embedded together with the circuit carrier in a molded body and the metal shaped part preferably expands when it melts and detaches the molded body from the circuit carrier by means of said expansion. The liquefied metal of the metal shaped part further preferably flows along a thus created gap between the circuit carrier and the molded body and connects the electrically conductive layers to one another. This advantageously makes it possible to cost-efficiently short-circuit the semiconductor switch by means of an electronic component, in particular a metal shaped part, configured on the circuit carrier.

The metal shaped part preferably has a wedge shape, a cuboid shape, a cylinder shape, a truncated pyramid shape or a truncated triangle shape.

A thus formed pointed shape can advantageously specify a crack propagation direction.

A trench or channel, in which the liquefied metal of the metal shaped body can flow, is preferably configured in the electrically conductive layer and/or in the electrically insulating layer. This advantageously makes it possible to achieve a quick short circuit of the semiconductor switch.

The present invention will be described in the following with reference to the figures and embodiment examples. Further advantageous design variants will emerge from a combination of the features disclosed herein.

### BRIEF DESCRIPTION OF THE DRAWINGS

FIG. 1 shows an embodiment example of a power semiconductor module according to the present invention comprising a semiconductor switch, the switching path connections of which can be connected low-ohmically by means of two metal shaped parts.

FIG. 2 shows the power semiconductor module depicted in FIG. 1, the switching path connections of which have been connected low-ohmically by means of two molten metal shaped parts.

FIG. 3 shows an embodiment example of a metal shaped part according to the present invention, the switching path connections of which can be connected low-ohmically by means of a metal shaped part, wherein the metal shaped part projects into an insulating trench configured between the switching path connections.

### DETAILED DESCRIPTION OF EXAMPLE EMBODIMENTS

FIG. 1 shows an embodiment example of a power semiconductor module 1. The power semiconductor module 1 comprises a circuit carrier 2 and at least one or only one power semiconductor switch 6. The power semiconductor switch 6 can be part of a semiconductor switch half-bridge. The circuit carrier 2 comprises an electrically insulating ceramic layer 3 and electrically conductive layers which are connected to the electrically insulating layer 3 in a material-locking manner, in particular by means of sintering.

The electrically conductive layers are copper layers, for instance, and are respectively formed on one side of the ceramic circuit carrier, in particular the electrically insulating layer 3. Of the electrically conductive layers, two electrically conductive layers 4 and 5 are shown, which are spaced apart from one another and separated by means of an insulating trench 11. The electrically conductive layers 4 and 5 are both connected to a switching path connection of the power semiconductor switch 6. The power semiconductor switch 6 is solder-connected or sinter-connected to the electrically conductive layer 4 with a switching path connection, in particular a drain connection. A further switching path connection, in particular a source connection, of the semiconductor switch 6 is connected to the electrically conductive layer 4 by means of an electrically conductive connection, in particular a bonding wire 7 or a soldered or sintered clip.

In this embodiment example, the insulating trench 11 has a width 12.

In this embodiment example, the power semiconductor module 1 comprises two metal shaped parts, wherein each metal shaped part is electrically connected, in particular soldered, to one of the electrically conductive layers in the area of the trench. A metal shaped part 8 is solder-connected to the electrically conductive layer 4 by means of a solder 10, and a metal shaped part 9 is solder-connected to the electrically conductive layer 5 by means of a solder 10.

The metal shaped parts 8 and 9 are both configured to melt at a predetermined temperature, in particular at a predetermined, in particular eutectic temperature, for example between 400 and 700 degrees Celsius, further for example between 300 and 500 degrees Celsius, and in so doing raise a molded body 14 of the power semiconductor module 1 in such a way that a gap is formed between the molded body 14 and the circuit carrier 2, in particular the electrically insulating layer 3, into which the liquefied metal shaped bodies 8 and 9 can flow, in particular flow toward one another. The electrically conductive layers 4 and 5 can thus be electrically connected to one another as a function of the predetermined temperature, in particular by means of the metal melt formed by the metal shaped parts 8 and 9.

The power semiconductor module 1, in particular the circuit carrier 2, also comprises a lacquer layer 13, which is connected to the electrically insulating layer 3 in the area of the insulating trench 11, and thus covers the insulating layer 3 in the area of the insulating trench 11. The lacquer layer 13 can facilitate the detachment of the casting compound 14, in particular the molded body, in particular the transfer molding compound of the power semiconductor module 1, when the metal shaped parts 8 and 9 expand in the area of the insulating trench 11.

In this embodiment example, the casting compound 14 covers the side of the circuit carrier 2 with which electronic components, in this embodiment example the power semiconductor switch 6, are connected to the circuit carrier 2. The metal shaped parts 8 and 9 can be connected to the circuit carrier 2 together with the power semiconductor switch 6 using an automated assembly process. The metal shaped parts 8 and 9 can be soldered or sintered to the circuit carrier 2. The power semiconductor switch 6 can be glued, soldered or sintered to the circuit carrier 2. In the case of a power module comprising a semiconductor switch half-bridge, the further power semiconductor switch of the semiconductor switch half-bridge can be bridged low-ohmically with two further metal shaped parts.

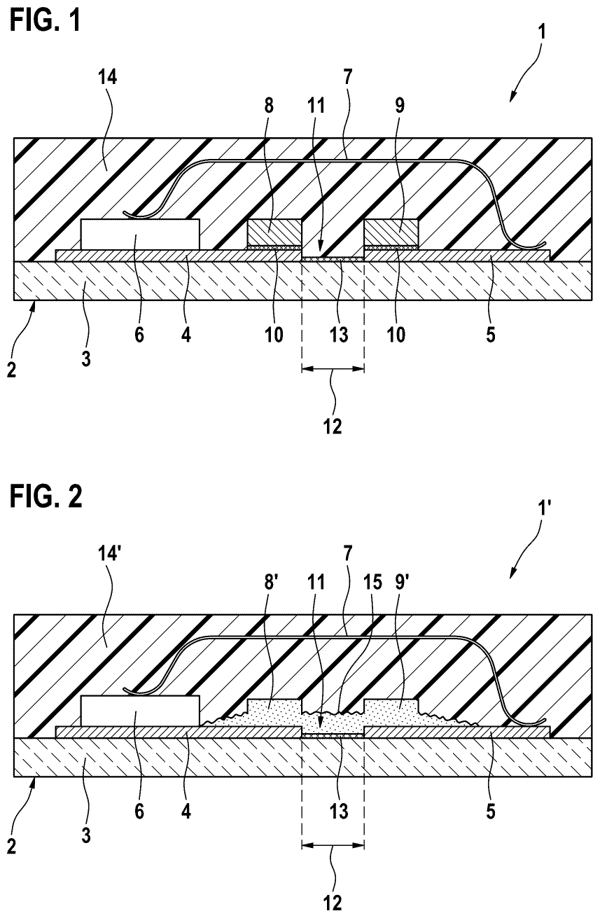

FIG. 2 shows the power semiconductor module 1′ depicted in FIG. 1, in which the casting compound 14′ is detached from the circuit carrier 2 in the area of the insulating trench 11. In the embodiment example shown in FIG. 2, the predetermined temperature, in particular 500 degrees Celsius, has been exceeded, so that the metal shaped parts 8′ and 9′ are at least partly or entirely molten and have thus been able to detach or spall the casting compound, in particular the molded body 14′, off the circuit carrier 2 in the area of the insulating trench 11.

FIG. 2 shows a gap 15, in which the liquefied metal shaped bodies 8′ and 9′ have flowed toward one another and have been mixed and/or combined with one another to form an electrically conductive melt. The electrically conductive layers 4 and 5 have thus been connected to one another by means of the electrically conductive melt in the area of the insulating trench 11, bridging the insulating trench 11 across the width 12 of the trench.

The bonding wire 7 is shown as an example, and is guided in this embodiment example in such a way that the electrical connection between the switching path connection, in particular the source connection of the power semiconductor switch 6, and the electrically conductive layer 5 remains intact when the molded body 14, in particular the broken-apart molded body 14′, breaks apart. The electrically conductive layers 4 and 5, and therefore the switching path connections of the power semiconductor switch 6, can thus remain securely connected to one another by means of the metal melt, both in the liquid state of the metal melt and in the cooled and thus solidified state of the metal melt which is formed by the metal shaped parts 8 and 9 that are now connected to one another in a material-locking manner.

An electric vehicle with an inverter which comprises at least one power semiconductor module can thus remain reliably short-circuited.

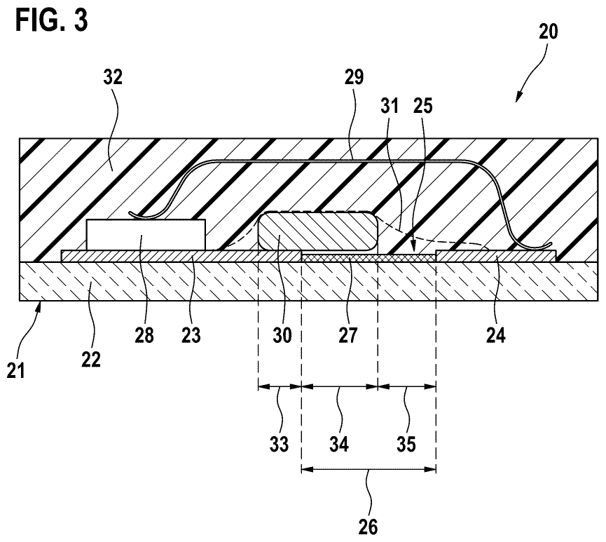

FIG. 3 shows an embodiment example of a power semiconductor module 20. The power semiconductor module 20 has a circuit carrier 21 which comprises an electrically insulating layer 22, in particular a ceramic layer, and at least two electrically conductive layers, of which the two electrically conductive layers 23 and 24 are shown as examples. The electrically conductive layers 23 and 24 are both connected to a switching path connection of the power semiconductor switch 28. The power semiconductor switch 28 is part of a semiconductor switch half-bridge of the power semiconductor module 20.

A switching path connection, in particular a source connection of the power semiconductor switch 28, is connected to the electrically conductive layer 24 by means of a bonding wire 29. The electrically conductive layer 23 is connected to a drain connection of the power semiconductor switch 28.

An insulating region, in this embodiment example an insulating trench 25, which in this embodiment example is at least partly or completely filled with a plastic layer 27, in particular a lacquer layer. is formed between the electrically conductive layers 23 and 24.

In this embodiment example, the power semiconductor module 20 comprises a, in particular only one, metal shaped part 30, which is electrically connected, in particular by means of soldering, to the electrically conductive layer 23 while resting on it at least partially.

The metal shaped part 30 thus projects with a longitudinal section 33 onto the electrically conductive layer 23 and overlaps said layer with said longitudinal section 33. The metal shaped part 30 projects with a longitudinal section 34 into the trench 25 and thus covers the insulating trench 25 over part of its trench width 26. An insulation distance 34 between the metal shaped part 30 and the electrically conductive layer 24 is configured such that no electrical flashover or electrical breakdown can occur between the metal shaped part 30 and the electrically conductive layer 24 during operation of the power semiconductor module 20.

In this embodiment example, the metal shaped part 30 forms a thermal fuse for the power semiconductor module 20. The metal shaped part 30 is configured to melt at a predetermined temperature, in particular a eutectic temperature, for example 500 degrees Celsius, and detach a molded body 32 of the power semiconductor module 20 from the circuit carrier 21 in the area of the insulating trench 25 and (as shown by a dashed gap 31) flow into the gap 31, and thus cover and electrically contact at least a part of the electrically conductive layer 24. This makes it possible to create an electrically conductive bridge, formed by the metal melt of the molten metal shaped body 30, which electrically connects the electrically conductive layers 23 and 24 to one another.

The plastic layer 27, in particular the lacquer layer, is designed to facilitate detachment of the molding compound of the molded body 32 from the circuit carrier 21 in the area of the insulating trench 25. The electrically conductive layer 24 can be coated with a metal layer, in particular a tin or silver layer, for example at least in the area of the insulating trench 25, so that an electrical connection, in particular a material-locking connection, of the metal melt of the liquefied metal shaped body 30 to the electrically conductive layer 24 can be facilitated.

The power semiconductor switch 28 and the metal shaped part 30 can respectively be glued, sintered or soldered to the circuit carrier 2, in particular the electrically conductive layer 23.

Unlike as shown in FIG. 3, the metal shaped body 30 can be connected to the electrically conductive layer 24 and project from the electrically conductive layer 24 into the insulating trench 25.

In this embodiment example, the metal shaped body 30 is disposed together with the power semiconductor switch 28 on the electrically conductive layer 23 and is connected to it in an electrically conductive manner. This advantageously makes it possible to create a predetermined potential on the metal shaped part 30, so that an electrical field between the metal shaped part 30 and the electrically conductive layer 24, and thus to the further switching path connection of the power semiconductor switch 28, can be predetermined.

In another embodiment, the metal shaped body 30 can be connected to the circuit carrier 2 in the area of the insulating trench 25 without being connected to one of the electrically conductive layers 23 or 24, and thus without being connected to a switching path connection of the power semiconductor switch 28.

An insulation distance between the metal shaped part 30 in this embodiment, in which the metal shaped part is insulated from the switching path connections of the power semiconductor switch, can be configured such that no electrical breakdown can occur via the metal shaped part 30 when an AC voltage, in particular an intermediate circuit voltage of an inverter, is applied to the electrically conductive layers 23 and 24.

What is claimed is:

1. A power semiconductor module, comprising:
a circuit carrier;
at least one semiconductor switch or semiconductor switch half-bridge connected to the circuit carrier, wherein the circuit carrier includes an insulating layer, and two electrically conductive layers which are separated from one another by an insulating region including an insulating trench, are both connected to the electrically insulating layer, and are both electrically connected to a switching path connection of: the semiconductor switch or the semiconductor switch half-bridge; and
at least one metal shaped body which is connected to the electrically conductive layer and configured to melt when the predetermined temperature is exceeded, to overcome the insulating region, and to electrically connect the electrically conductive layers separated from one another by the insulating region to one another.

2. The power semiconductor module according to claim 1, wherein the electrically conductive layers are disposed in a common plane formed by the electrically insulating layer.

3. The power semiconductor module according to claim 1, wherein the metal shaped body is formed by a metal shaped part including a solder preform, which is soldered to the circuit carrier with a solder that has a lower melting temperature than the metal shaped body.

4. The power semiconductor module according to claim 1, wherein: (i) the semiconductor switch or the semiconductor switch half-bridge, and (ii) the metal shaped body, are embedded using a plastic molding compound, and the metal shaped body is configured to create a gap between the plastic compound and the circuit carrier in an area of the insulating region when it melts and thus bridge the insulating region and electrically connect the electrically conductive layers to one another.

5. The power semiconductor module according to claim 4, wherein, in the area of the insulating region, the circuit carrier includes an adhesion-reducing layer which covers the electrically insulating layer, so that the plastic molding compound can be detached there from the circuit carrier when the metal shaped body expands.

6. The power semiconductor module according to claim 5, wherein the adhesion-reducing layer is a lacquer layer.

7. The power semiconductor module according to claim 1, wherein the metal shaped body is formed by a metal foam.

8. The power semiconductor module according to claim 1, wherein the metal shaped body includes tin.

9. The power semiconductor module according to claim 1, wherein the at least one metal shaped body includes metal shaped bodies which can flow toward one another when they melt, and are configured on both of the electrically conductive layers.

10. An electric vehicle, comprising:
an inverter with at least one power semiconductor module, the power semiconductor module including:
a circuit carrier,
at least one semiconductor switch or semiconductor switch half-bridge connected to the circuit carrier, wherein the circuit carrier includes an insulating layer, and two electrically conductive layers which are separated from one another by an insulating region including an insulating trench, are both connected to the electrically insulating layer, and are both electrically connected to a switching path connection of: the semiconductor switch or the semiconductor switch half-bridge, and
at least one metal shaped body which is connected to the electrically conductive layer and configured to melt when the predetermined temperature is exceeded, to overcome the insulating region, and to electrically connect the electrically conductive layers separated from one another by the insulating region to one another;
wherein the inverter is connected to at least one electric drive machine of the electric vehicle and is configured to supply current to the drive machine to produce a rotating magnetic field.

11. A method for deactivating an inverter of an electric vehicle, the method comprising the following steps:
short-circuiting at least one power semiconductor switch of the inverter using a metal shaped part that melts when the inverter overheats, wherein the metal shaped part is disposed and configured to bridge two spaced-apart electrically conductive layers of a circuit carrier of the inverter.

12. The method according to claim 11, wherein, the power semiconductor switch is embedded together with the circuit carrier in a molded body, and the metal shaped part expands when it melts and detaches the molded body from the circuit carrier, and electrically connects the electrically conductive layers as it flows along a created gap.
